(19) United States
(12) Patent Application Publication
(10) Pub. No.: US 2003/0025556 A1
(43) Pub. Date: Feb. 6, 2003

(54) Differential amplifier providing precisely balanced output signals and having low power consumption

(75) Inventor: Mitsuhiro Muraoka, Yamagata (JP)

Correspondence Address: SUGHRUE, MION, ZINN,, MACPEAK & SEAS, 2100 Pennsylvania Avenue, N.W., Washington, DC, 20037, US

(73) Assignee: NEC COMPOUND SEMICONDUCTOR DEVICES, LTD.

(21) Appl. No.: 10/200,210

(22) Filed: Jul. 23, 2002

(30) Foreign Application Priority Data
Jul. 31, 2001 (JP) 2001-231331

(51) Int. Cl. H03F 3/45

(52) U.S. Cl. 330/252

(57) ABSTRACT

A differential amplifier which provides a precise phase difference of 180 degrees between a pair of differential output signals and which has low power consumption. The differential amplifier comprises a differential amplifying stage which has a differential pair of transistors. An unbalanced input signal is applied to the control electrode of one of the transistors and a pair of differential signals are outputted from a pair of output nodes of the differential amplifying stage. The differential amplifier also has a signal delay element, coupled between the output node on the side of the transistor to which the unbalanced input signal is applied and an output terminal of the differential amplifier, for compensating the phase difference. The signal delay element may have a plurality of taps for precisely adjusting the phase difference.

### FIELD OF THE INVENTION

The present invention relates generally to a differential amplifier, and more particularly to a differential amplifier which has a precise phase difference of 180 degrees between a pair of differential output signals and which has low power consumption.

### BACKGROUND OF THE INVENTION

A differential amplifier is generally used for obtaining a pair of amplified differential output signals from a pair of differential input signals. However, sometimes, unbalanced input signals are supplied to a pair of input terminals of a differential amplifier. That is, an input signal is supplied to one of the pair of input terminals, and the other one of the pair of input terminals is connected to the ground.

FIG. 7 is a circuit diagram showing a conventional improved differential amplifier 10, as a first prior art example, which receives a single unbalanced input signal and converts the input signal into a pair of balanced output signals.

The conventional improved differential amplifier 10 shown in FIG. 7 comprises a first differential amplifying stage 11, a level shifting stage 12 and a second differential amplifying stage 13.

The first differential amplifying stage 11 comprises a pair of bipolar transistors 15 and 16. The emitter electrodes of the bipolar transistors 15 and 16 are coupled to each other and to the ground via a constant current source 45. The base electrode of the transistor 15 is coupled to an input terminal 22, and the base electrode of the transistor 16 is coupled to the ground via a capacitor 47. The collector electrode of the transistor 15 is coupled to a power supply terminal 51 via a resistor 19. The collector electrode of the transistor 16 is coupled to the power supply terminal 51 via a resistor 20.

The level shifting stage 12 comprises a pair of bipolar transistors 29 and 30, and a pair of constant current sources 49 and 50. The bases of the transistors 29 and 30 are coupled to the collectors of the transistors 16 and 15 of the first differential amplifying stage 11, respectively. The emitters of the transistors 29 and 30 are coupled to the ground via the constant current sources 49 and 50, respectively. The collectors of the transistors 29 and 30 are both coupled to the power supply terminal 51. The transistor 29 and the current source 49 constitute an emitter follower, and the transistor 30 and the current source 50 constitute an emitter follower.

The second differential amplifying stage 13 comprises a pair of bipolar transistors 33 and 34. The emitter electrodes of the bipolar transistors 33 and 34 are coupled to each other and to the ground via a constant current source 35. The base electrode of the transistor 33 is coupled to the emitter electrode of the transistor 30, and the base electrode of the transistor 34 is coupled to the emitter electrode of the transistor 29. The collector electrode of the transistor 33 is coupled to the power supply terminal 51 via a resistor 36. The collector electrode of the transistor 34 is coupled to the power supply terminal 51 via a resistor 37. The collectors of the transistors 33 and 34 are coupled to output terminals 41 and 43, respectively.

In the first differential amplifying stage 11, an unbalanced high frequency signal, i.e., an unbalanced input signal, is applied to the base of the transistor 15, via the input terminal 22. Thereby, current values of currents flowing through the resistor 19 and the resistor 20 vary depending on the value of the unbalanced input signal. Therefore, the collector potentials of the transistors 15 and 16 also vary, and a pair of signals having a phase difference are obtained at output terminals, i.e., the collectors, of the transistors 15 and 16. The variations of collector potentials of the transistors 15 and 16 are transmitted to the second differential amplifying stage 13 via a pair of transistors 30 and 29 of the level shifting stage 12.

In the second differential amplifying stage 13, when the variations of the collector potentials of the transistors 15 and 16 are applied to the bases of the transistors 33 and 34, the emitter potentials of the transistors 33 and 34 vary in response to the variation. Thereby, a current flowing through the resistor 36 and the main current path of the transistor 33 into the constant current source 35 and a current flowing through the resistor 37 and the main current path of the transistor 34 into the constant current source 35 vary respectively. Thereby, a pair of output signals are obtained from the output terminals 41 and 43 which have a correct relative phase difference of 180 degrees.

In the recent mobile communication market, circuits are required which operate in a frequency equal to or higher than 500 MHz. Also, it is required that the phase difference between output signals of a differential amplifier is correctly 180 degrees, that the differential amplifier has low power consumption, and the like. In the above-mentioned differential amplifier 10, it is impossible to obtain the correct phase difference of 180 degrees between the signals at the output terminals 25 and 27, only by using the first differential amplifying stage 11 which is an unbalanced amplifying stage, because of the influence caused by the differences in electrical signal lengths, stray capacitance and the like. Therefore, by also using the second differential amplifying stage 13 which operates under the condition of differential input signals and differential output signals, the phase difference of 180 degrees is obtained between the differential output signals, and the above-mentioned requirement of phase difference is fulfilled.

However, in the circuit shown in FIG. 7, in order to directly couple the first differential amplifying stage 11 and the second differential amplifying stage 13 and to secure a wide linearity range of differential amplification, it is necessary to use a high power supply voltage. Therefore, by coupling the first differential amplifying stage 11 and the second differential amplifying stage 13 via the level shifting stage 12, it becomes possible to realize a relatively wide linearity range of differential amplification even when the power supply voltage is not so high. Thereby, in the differential amplifier 10 of the first prior art example, a circuit scale becomes large, an operating current becomes large and it is impossible to realize a differential amplifier having low power consumption.

Japanese patent laid-open publication No. 6-350358 discloses an unbalanced-balanced conversion circuit, as a second prior art example, which has a smaller circuit scale than that of the differential amplifier according to the first prior art example. FIG. 8 is a circuit diagram showing the unbalanced-balanced conversion circuit disclosed in this publication.

The conversion circuit shown in FIG. 8 comprises a differential amplifying stage 74 and a signal delay stage 75.

The differential amplifying stage 74 comprises a pair of bipolar transistors 76 and 77. The emitter electrodes of the bipolar transistors 76 and 77 are coupled to one terminal of a constant current source via resistors. The other terminal of the constant current source is grounded. The base electrode of the transistor 76 is coupled to an input terminal 73, and the base electrode of the transistor 77 is coupled to the ground via a capacitor. The collector electrode of the transistor 76 is coupled to a power supply terminal 71 via a resistor. The collector electrode of the transistor 77 is coupled to the power supply terminal 71 via a resistor.

The signal delay stage 75 comprises a pair of bipolar transistors 78 and 79. The bases of the transistors 78 and 79 are coupled to the collectors of the transistors 76 and 77 of the differential amplifying stage 74, respectively. The emitter of the transistor 78 is coupled to the ground via a series connection of resistors 80 and 81. The emitter of the transistor 79 is coupled to the ground via a resistor 82. The collectors of the transistors 78 and 79 are both coupled to the power supply terminal 71. A circuit connection point between the resistors 80 and 81 is coupled to one output terminal of the differential amplifier 72, and the emitter of the transistor 79 is coupled to the other output terminal of the differential amplifier 72.

In the unbalanced-balanced conversion circuit shown in FIG. 8, the differential amplifying stage 74 accepts an unbalanced high frequency signal inputted from the input terminal 73, and converts the unbalanced high frequency signal into a pair of differential signals which are outputted from the differential amplifying stage 74. The signal delay stage 75 accepts the pair of differential signals from the differential amplifying stage 74, and outputs the pair of differential signals as a pair of balanced output signals whose relative phase difference is precisely adjusted to 180 degrees.

That is, in the unbalanced-balanced conversion circuit 72, there is provided the differential amplifying stage 74 which has a pair of transistors 76 and 77 and which has a similar structure to that of the first differential amplifying stage 11 of FIG. 7. Also, there is provided the signal delay stage 75 which is disposed at a later stage of the differential amplifying stage 74 and which replaces the level shifting stage 12 and the second differential amplifying stage 13 of FIG. 7. Thereby, it becomes possible to obtain a pair of output signals having a correct relative phase difference of 180 degrees.

In the above-mentioned second prior art example, it is necessary to dispose the signal delay stage 75 which comprises a pair of transistors 78 and 79 and resistors 80-82 to obtain a pair of output signals having a correct relative phase difference of 180 degrees. Therefore, although the circuit scale of the second prior art example is smaller than that of the first prior art example, the circuit scale is still large and it is still difficult to sufficiently decrease power consumption of a differential amplifier circuit.

### SUMMARY OF THE INVENTION

Therefore, it is an object of the present invention to provide a differential amplifier which provides a pair of output signals having a precise relative phase difference of 180 degrees and which has lower power consumption than that of the conventional differential amplifiers.

It is another object of the present invention to provide a differential amplifier which provides a pair of output signals having a precise relative phase difference of 180 degrees, which is suitable for use in an integrated circuit device and which has lower power consumption than that of the conventional differential amplifiers.

It is still another object of the present invention to provide a differential amplifier which provides a pair of output signals having a precise relative phase difference of 180 degrees even in a high frequency range and which has lower power consumption than that of the conventional differential amplifiers.

It is still another object of the present invention to provide a differential amplifier in which a relative phase difference between a pair of output signals can be adjusted to a precise value of 180 degrees or other desired value and which has lower power consumption than that of the conventional differential amplifiers.

It is still another object of the present invention to provide a differential amplifier in which a relative phase difference between a pair of output signals can be adjusted to a precise value of 180 degrees or other desired value in a desired frequency range and which has lower power consumption than that of the conventional differential amplifiers.

It is still another object of the present invention to provide a differential amplifier which provides a pair of output signals having a precise relative phase difference of 180 degrees in various operating frequency range and which has lower power consumption than that of the conventional differential amplifiers.

It is still another object of the present invention to obviate the disadvantages of the conventional differential amplifier.

According to an aspect of the present invention, there is provided a differential amplifier comprising: a differential amplifying stage which has a differential pair of transistors, wherein an unbalanced input signal is applied to the control electrode of one of the transistors and a pair of differential signals are outputted from a pair of output nodes of the differential amplifying stage; and a signal delay element, coupled between the output node on the side of the transistor to which the unbalanced input signal is applied and an output terminal of the differential amplifier, for delaying a signal outputted from the output node.

In this case, it is preferable that the differential pair of transistors comprise bipolar transistors.

It is also preferable that the signal delay element comprises a spiral inductor.

It is further preferable that the signal delay element comprises a redundant wiring conductor.

It is advantageous that the signal delay element has a plurality of taps for providing output signals having mutually different delay times.

It is also advantageous that the differential amplifying stage and the signal delay element are formed on the same semiconductor substrate.

It is further advantageous that the differential amplifier is formed as a monolithic integrated circuit device.

In the differential amplifier according to the present invention, it is possible to use a simple structure which comprises one differential amplifying stage and a signal delay element coupled to the output side of the differential amplifying stage having a shorter signal path. By using such simple structure, a phase advance of one of differential signals with respect to the other one of the differential signals can be suppressed. Thereby, it becomes possible to adjust the phase difference between the signals of the first and second output terminals into a precise value of 180 degrees. Therefore, when compared with the above-mentioned first and second prior art examples, it is possible to further decrease a circuit scale and power consumption of a differential amplifier.

By using a spiral inductor and/or a redundant wiring conductor as the signal delay element, it is possible to easily adjust the phase difference and to decrease power consumption.

Generally, in a differential amplifier, the phase difference between a pair of output signals becomes large as a frequency of an input signal becomes high. In the present invention, a plurality of taps are selectively used as a terminal for a high frequency application having a larger phase difference, a terminal for a low frequency application having a smaller phase difference, and the like. Therefore, it is possible to obtain an advantageous effect that the usable frequency range of the differential amplifier can be expanded by appropriately selecting the output terminal through which a desired delay time is provided.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1 is a circuit diagram showing a differential amplifier according to a first embodiment of the present invention;

FIG. 2 is a schematic plan view illustrating a concrete example of a signal delay element used in the differential amplifier according to the first embodiment of the present invention;

FIG. 3 is a schematic plan view illustrating another concrete example of the signal delay element used in the differential amplifier according to the first embodiment of the present invention;

FIG. 4 is a circuit diagram showing a differential amplifier according to a second embodiment of the present invention;

FIG. 5 is a schematic plan view showing a signal delay element which uses a spiral inductor and which is used in the differential amplifier according to the second embodiment of the present invention;

FIG. 6 is a schematic plan view showing a signal delay element which uses a redundant wiring conductor and which is used in the differential amplifier according to the second embodiment of the present invention;

FIG. 7 is a circuit diagram showing a conventional differential amplifier, as a first prior art example, which receives a single unbalanced input signal and converts the input signal to a pair of balanced output signals; and

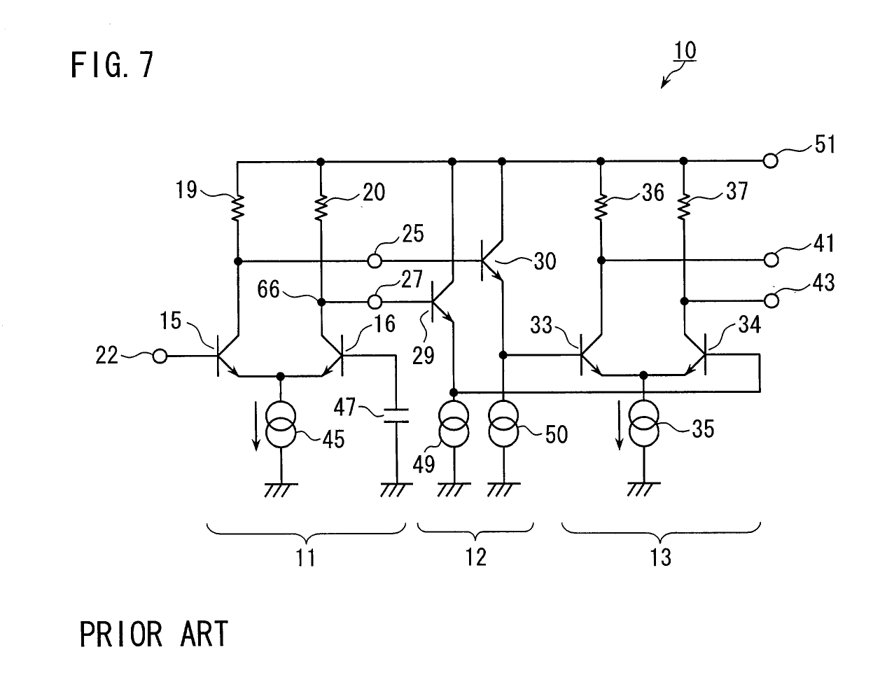

FIG. 8 is a circuit diagram showing a conventional unbalanced-balanced conversion circuit as a second prior art example.

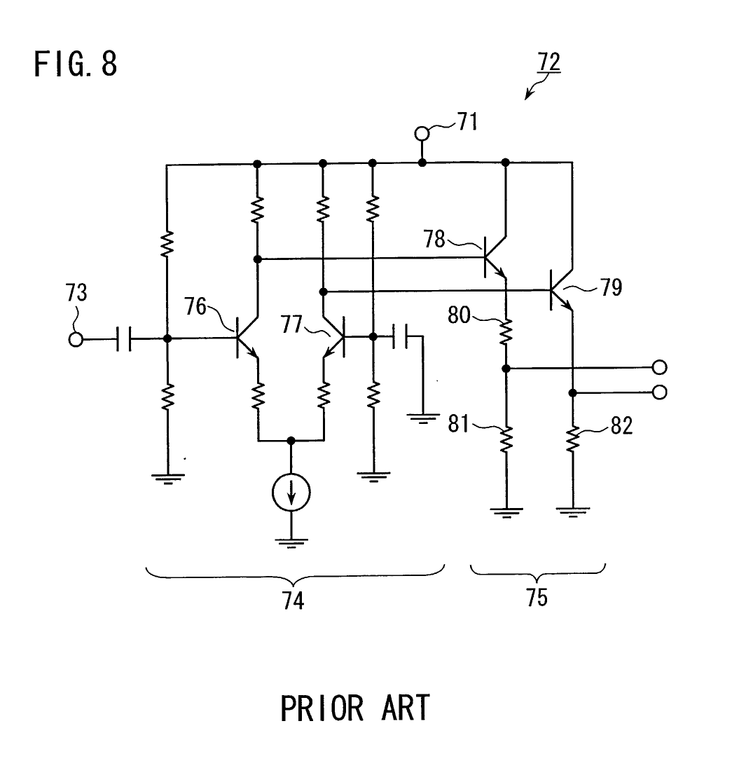

### DESCRIPTION OF A PREFERRED EMBODIMENT

With reference to the drawings, embodiments of the present invention will now be described in detail.

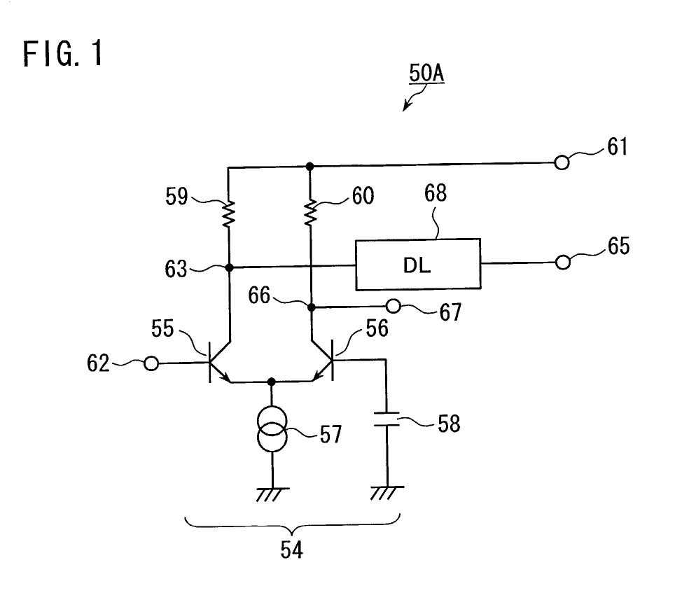

FIG. 1 is a circuit diagram showing a differential amplifier according to a first embodiment of the present invention which is constituted as a monolithic integrated circuit device.

The differential amplifier 50A shown in FIG. 1 comprises a differential amplifying stage 54 and a signal delay element (DL) 68.

The differential amplifying stage 54 comprises a pair of bipolar transistors (hereafter, simply called transistors) 55 and 56. The emitter electrodes of the transistors 55 and 56 are coupled to each other and to the ground via a constant current source 57. The control electrode, i.e., the base electrode of the transistor 55 is coupled to an input terminal 62, and the base electrode of the transistor 56 is coupled to the ground via a capacitor 58. In practice, an appropriate DC bias voltage is applied to the base electrode of the transistor 56 from a bias circuit and the like. However, for the sake of simplicity, detailed illustration and description of such bias circuit and the like are omitted here. The collector electrode of the transistor 55 is coupled to a power supply terminal 61 via a resistor 59. The collector electrode of the transistor 56 is coupled to the power supply terminal 61 via a resistor 60.

An output node 63, i.e., the collector of the transistor 55, to which one end of the resistor 59 is coupled, is coupled to a first output terminal 65, via the signal delay element 68. An output node 66, i.e., the collector of the transistor 56, to which one end of the resistor 60 is coupled, is coupled to a second output terminal 67.

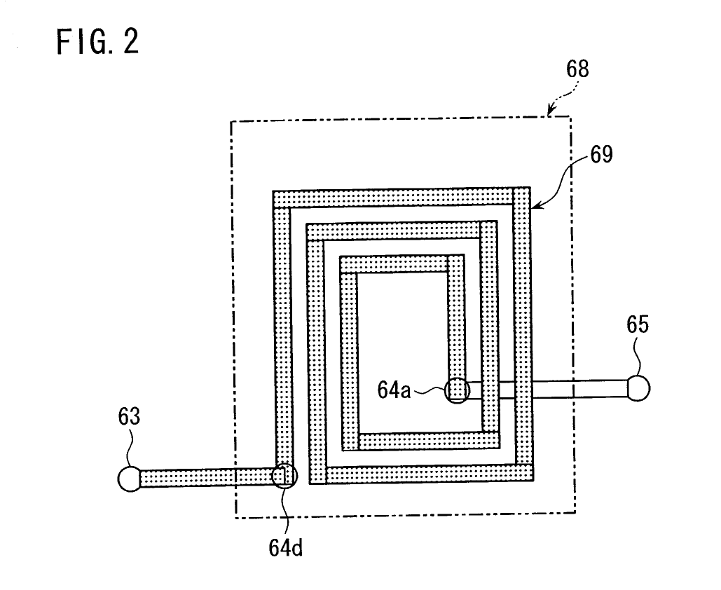

FIG. 2 is a schematic plan view illustrating a concrete example of the signal delay element 68. In the example of FIG. 2, the signal delay element 68 is constituted by using a spiral inductor 69 which is a passive element. The spiral inductor 69 is made by forming a conductive film on a semiconductor substrate on which the differential amplifier 50A is formed, and by patterning the conductive film into a spiral shaped wiring conductor or a coil wire having a predetermined width and thickness. A terminal 64a of an inner end of the spiral shaped wiring conductor is coupled to the first output terminal 65. Also, a terminal 64d of an outer end of the spiral shaped wiring conductor is coupled with the output node 63.

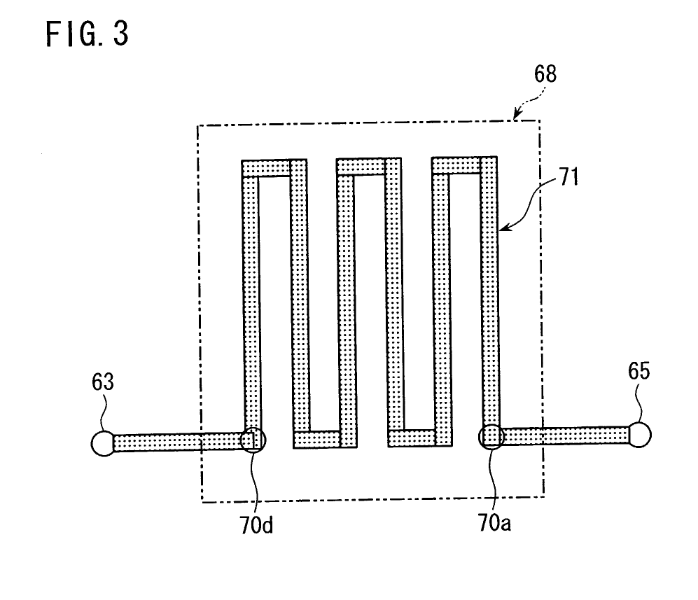

FIG. 3 is a schematic plan view illustrating another concrete example of the signal delay element 68. In the example of FIG. 3, the signal delay element 68 is constituted by using a redundant wiring conductor 71 which is a serpentine shaped wiring conductor, in this example. That is, the redundant wiring conductor 71 is a passive element in which a signal transmission distance is extended by detouring the wiring conductor between the output node 63 and the first output terminal 65. A terminal 70a of one end of the redundant wiring conductor 71 is coupled to the first output terminal 65. Also, a terminal 70d of the other end of the redundant wiring conductor 71 is coupled with the output node 63.

In the differential amplifier 50A, an unbalanced high frequency signal, i.e., an unbalanced input signal, is applied to the base of the transistor 55, via the input terminal 62. Thereby, an emitter potential of the transistor 55 varies and current values of currents flowing through the resistor 59 and the resistor 60 vary depending on the value of the unbalanced input signal. Therefore, the collector potentials of the transistors 55 and 56 also vary, and a pair of differential signals having a phase difference are obtained at a pair of output nodes 63 and 66.

Here, one of the differential signals which is transmitted from the output node 63 on the side of the transistor 55 to the first output terminal 65 is previously delayed by a predetermined delay time via the spiral inductor 69 or the redundant wiring conductor 71 of the signal delay element 68. Thereby, phase advance is suppressed or compensated. Therefore, it becomes possible to output a pair of signals having a correct relative phase difference of 180 degrees, i.e., balanced output signals, from the first and second output terminals 65 and 67.

That is, in the differential amplifier 50A, the unbalanced input signal applied to the base of the transistor 55 is amplified and converted into a first signal which is outputted from the first output terminal 65 via the transistor 55 and the output node 63, and a second signal which is outputted from the second output terminal 67 via the transistor 55, the transistor 56 and the output node 66. The electrical length of the signal path of the second signal from the input terminal 62 to the output terminal 67 is longer than the electrical length of the signal path of the first signal from the input terminal 62 to the output node 63. Also, the parasitic capacitance of the transistor 56 and the like have a larger influence on the second signal. Therefore, the phase of the second signal delays with respect to the first signal. However, according to the present invention, the signal delay element 68 is inserted into the signal path of the first signal, that is, the signal delay element 68 is inserted on the side of the output terminal of the differential amplifying stage having a shorter signal path length. Therefore, it is possible to suppress the phase advance of the first signal, and to make the relative phase difference between the signals of the output terminals 65 and 67 precisely 180 degrees.

In this way, according to the structure of the differential amplifier 50A, it is possible to output a pair of signals having the precise relative phase difference of 180 degrees even in a high frequency range. Such operation is realized by using a simple circuit structure which comprises only one stage of the differential amplifying stage 54 and the signal delay element 68 that delays one of the output signals and that is coupled to the differential amplifying stage 54. Therefore, it is possible to realize a differential amplifier which can output balanced output signals having a correct phase difference of 180 degrees from an unbalanced input signal, for example, in a frequency range equal to or higher than 500 MHz. Such differential amplifier can be constituted on a circuit scale smaller than that of the conventional differential amplifier having a plurality of differential amplifying stages.

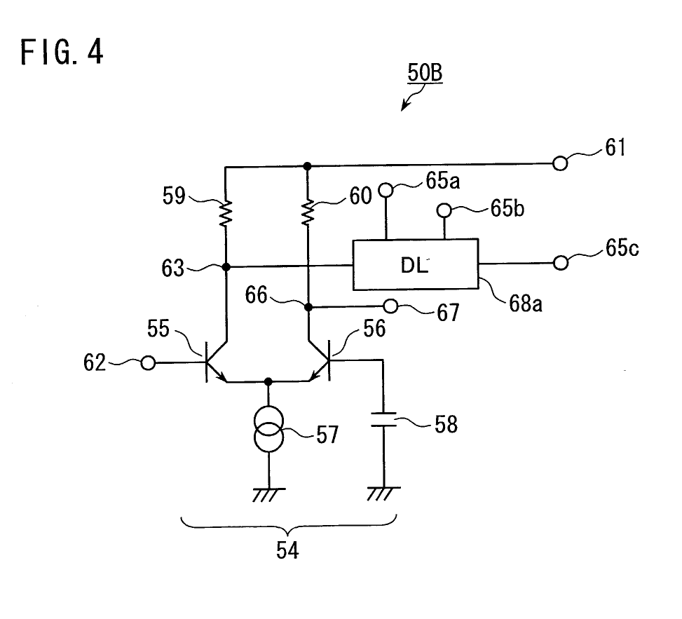

FIG. 4 is a circuit diagram showing a differential amplifier 50B according to a second embodiment of the present invention. In FIG. 4, the same reference numerals designate the identical or corresponding components with those in FIG. 1. The differential amplifier 50B shown in FIG. 4 is substantially the same as that of FIG. 1 except that the signal delay element 68 in FIG. 1 is replaced by a signal delay element 68a.

In the differential amplifier 50B, the signal delay element (DL) 68a has a plurality of taps, and respective taps are coupled to output terminals 65a, 65b and 65c each of which becomes a first output terminals. The number of the taps may be any desired number. Also, for example, the number of output terminals may be one, and a previously selected one of the taps of the signal delay element 68a may be coupled to the output terminal, by appropriately patterning a conductive wire.

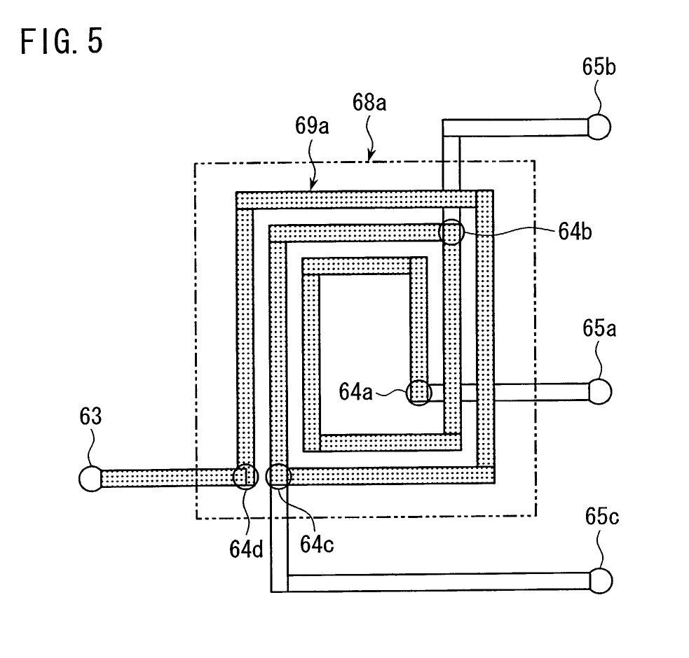

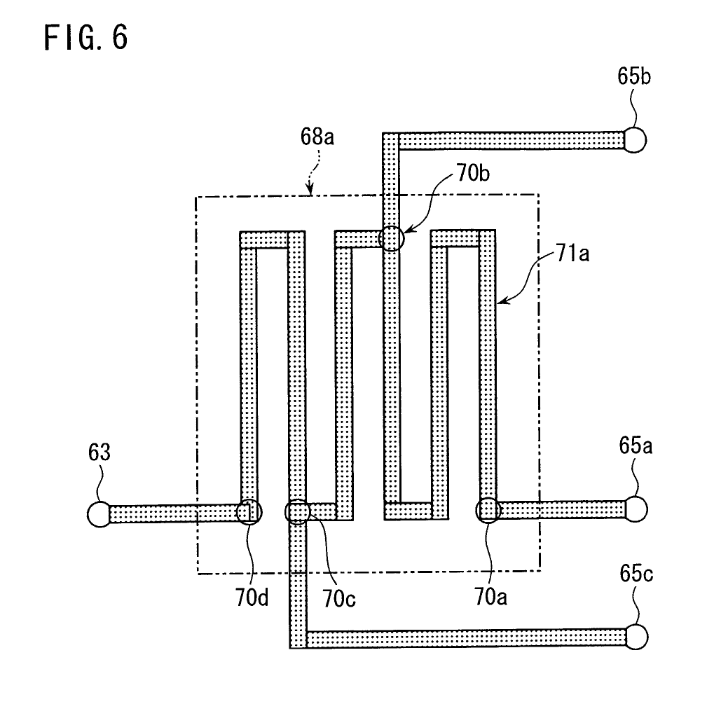

As examples of concrete structures of the signal delay element 68a according to this embodiment, FIG. 5 shows a signal delay element which uses a spiral inductor 69a, and FIG. 6 shows a signal delay element which uses a redundant wiring conductor 71a.

In the example of FIG. 5, the signal delay element 68a is constituted by using a spiral inductor 69a which is a passive element. The spiral inductor 69a is made by forming a conductive film on a semiconductor substrate on which the differential amplifier 50B is formed, and by patterning the conductive film into a spiral shaped wiring conductor or a coil wire having a predetermined width and thickness. A terminal 64a of an inner end of the spiral shaped wiring conductor is coupled to the output terminal 65a. Also, a terminal 64d of an outer end of the spiral shaped wiring conductor is coupled with the output node 63.

Further, in the spiral inductor 69a shown in FIG. 5, there are provided terminals or taps 64b and 64c between the terminal or tap 64a of an inner end of the spiral shaped wiring conductor and the terminal or tap 64d of an outer end of the spiral shaped wiring conductor. The terminals or taps 64b and 64c are disposed at different locations of the spiral shaped wiring conductor such that predetermined delay times are obtained stepwise.

FIG. 6 is a schematic plan view illustrating another concrete example of the signal delay element 68a. In the example of FIG. 6, the signal delay element 68a is constituted by using a redundant wiring conductor 71a which is a serpentine shaped wiring conductor, in this example. That is, the redundant wiring conductor 71a is a passive element in which a signal transmission distance is extended by detouring the wiring conductor between the output node 63 and the output terminal 65a. A terminal 70a of one end of the redundant wiring conductor 71a is coupled to the output terminal 65a. Also, a terminal 70d of the other end of the redundant wiring conductor 71a is coupled with the output node 63.

In the redundant wiring conductor 71a shown in FIG. 6, there are provided terminals or taps 70b and 70c between the terminal or tap 70a of an inner end of the spiral shaped wiring conductor and the terminal or tap 70d of an outer end of the spiral shaped wiring conductor. The terminals or taps 70b and 70c are disposed at different locations of the redundant wiring conductor 71a such that predetermined delay times are obtained stepwise.

By using the signal delay element 68a having the above-mentioned structures and the like, it is possible to realize output terminals 65a-65c having different delay times by using a simple structure, and to make the length of the delay time vary stepwise depending on the connection nodes.

Usually, in a differential amplifier, the phase difference between a pair of output signals becomes large as a frequency of an input signal becomes high. In the above-mentioned embodiments, for example, the output terminal 65a can be used in a high frequency application, and the output terminal 65c can be used in a low frequency application. Also, the output terminal 65b can be used in a medium frequency application. Therefore, in this embodiment, in addition to the advantageous effect obtained by the first embodiment, it is possible to obtain an advantageous effect that the usable frequency range of the differential amplifier can be expanded by appropriately selecting the output terminal through which a desired delay time is provided.

In the above-mentioned first and second embodiments, assume that, at a high frequency, for example, of 2 GHz, the phase difference between the second signal which is transmitted via a path from the transistor 55, via the transistor 56 to the second output terminal 67 and the first signal which is transmitted via a path from the transistor 55 to the first output terminal 65 (65a-65c) is 170 degrees. In such case, if the signal delay element 68 or 68a is constituted to have a phase retard of 10 degrees, it is possible to obtain a pair of output signals having a correct phase difference of 180 degrees. It is also possible to obtain a desired value of the phase difference by changing the delay time of the signal delay element 68 or 68a.

In the above-mentioned embodiments, the differential amplifying stage comprises a pair of bipolar transistors. However, the present invention is not limited to such bipolar transistors, but it is also possible to use other elements such as MOSFET's and the like.

As mentioned above, according to the present invention, it is possible to obtain a differential amplifier which provides a pair of output signals having a precise relative phase difference of 180 degrees and which has a smaller circuit scale than that of the conventional differential amplifiers.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as falling within the scope of the appended claims.

What is claimed is:

1. A differential amplifier comprising:
a differential amplifying stage which has a differential pair of transistors, wherein an unbalanced input signal is applied to the control electrode of one of the transistors and a pair of differential signals are outputted from a pair of output nodes of the differential amplifying stage; and
a signal delay element, coupled between the output node on the side of the transistor to which the unbalanced input signal is applied and an output terminal of the differential amplifier, for delaying a signal outputted from the output node.

2. A differential amplifier as set forth in claim 1, wherein the differential pair of transistors comprise bipolar transistors.

3. A differential amplifier as set forth in claim 1, wherein the signal delay element comprises a spiral inductor.

4. A differential amplifier as set forth in claim 1, wherein the signal delay element comprises a redundant wiring conductor.

5. A differential amplifier as set forth in claim 1, wherein the signal delay element has a plurality of taps for providing output signals having mutually different delay times.

6. A differential amplifier as set forth in claim 1, wherein the differential amplifying stage and the signal delay element are formed on the same semiconductor substrate.

7. A differential amplifier as set forth in claim 1, wherein the differential amplifier is formed as a monolithic integrated circuit device.
